(19) United States
(12) Patent Application Publication
(10) Pub. No.: US 2006/0151313 A1
(43) Pub. Date: Jul. 13, 2006

(54) Thin film battery, anode film for thin film battery and preparation method thereof

(75) Inventors: Maw-Kuen Wu, Taipei (TW); Chia-Lin Wang, Huatan Township (TW); Yang-Chung Liao, Ji-an Township (TW); Nyan-Hwa Tai, Hsinchu (TW); Fong-Chi Hsu, Chu-Tung City (TW)

Correspondence Address: TRANSPACIFIC LAW GROUP, 617 NORTH DELAWARE STREET, SAN MATEO, CA, 94401, US

(73) Assignee: Academia Sinica

(21) Appl. No.: 11/035,855

(22) Filed: Jan. 13, 2005

(51) Int. Cl. C23C 14/00

(52) U.S. Cl. 204/192.15

(57) ABSTRACT

Method for preparation of anode film for thin film battery comprises: providing a target material to provide Li ion and Ti ion and a substrate comprising a base layer, a buffer layer and a precious metal current collector layer; sputtering LiMO layer on a said substrate at high temperature in a vacuum chamber and obtaining the anode film for thin film battery of this invention. In this invention, material for the precious metal current collector may be a precious metal such as Ag, Au, Pt etc., the alloy and oxides of these metals. The sputtering temperature may be above 300° C., preferably above 500° C. and most preferably above 650° C. The anode thin film material so prepared may be Li₄Ti₅O₁₂. This invention also discloses anode film so prepared and thin film battery using such anode film.

### FIELD OF THE INVENTION

The present invention relates to a thin film battery, especially to anode film for thin film battery.

### BACKGROUND OF THE INVENTION

Along with the rapid development of technology, sizes of electronic devices and power required in electronic components are shrinking day by day. The thin film battery, with its appearance as a thin film, has caught the attention of the industry. Besides its miniature size, it expresses the advantages of very long life times, high safety, high versatility in shape, low leakage rate and could be incorporated into integrated circuit or respective electronic components.

The structure of the thin film battery is just the same as that of ordinary batteries. It is consisted by the electrolyte layer sandwiched by the cathode and anode. The major feature of thin film battery, in comparison with ordinary batteries, is that the components of thin film battery are all solid-state materials. That's why the thin film battery is also called solid-state thin film battery.

Materials that may be used as anode of thin film battery include: lithium, lithium oxides, and lithium based transition-metal oxides. However, because most anode materials will have a large irreversible capacity in its first run of charge and discharge, which the irreversible capacity will decrease the endurance of the battery. Among the lithium based transition-metal oxides, Li₄Ti₅O₁₂ possesses advantages such as, an excellent reversibility in charge-discharge, a flat working voltage, long cyclic life times etc. and thus is considered as a proper material for the anode of thin film battery.

So far, the conventional preparation of Li₄Ti₅O₁₂ film includes the steps of: casting a sol-gel layer onto a substrate and applying a high temperature annealing process to the assembly to obtain a crystallized Li₄Ti₅O₁₂ film. The advantages of the sol-gel method include: easy to controll the composition, nano-scale particles, low preparation cost and high deposition rate etc. However, the sol-gel process can not be applied to the fabrication of integrated circuit or be incorporated into an individual electronic device. On the other hand, thin film prepared by sputtering has a better uniformity in distribution; its composition and geometry are easy to control. As a result, how to prepare a Li₄Ti₅O₁₂ film with desired functionality has become an important task for experts in this field.

### OBJECTIVES OF THE INVENTION

The objective of this invention is to provide a novel thin film battery and a anode film that may be used in the thin film battery.

Another objective of this invention is to provide a method for the preparation of thin film battery and its anode film.

Another objective of this invention is to provide a method for the preparation of thin film battery that uses the LiMO as its anode material and the anode film so prepared.

Another objective of this invention is to provide a method for the preparation of anode film that may be used in the manufacture process of integrated circuit.

### SUMMARY OF THE INVENTION

According to the method for the preparation of anode film for thin film battery, a target material to provide Li and Ti ions and a substrate comprising a base layer, a buffer layer and a noble metal current collector layer, are first prepared. Sputter a LIMO layer onto the substrate in vacuum chamber at high temperature to obtain the anode film for thin film battery of this invention. In this invention, the noble metal current collector layer may contain noble metals such as silver, gold, platinum etc. and their alloy or oxides. The sputtering temperature may be above 300° C., preferably above 500° C. and most preferably above 650° C. The anode film so prepared may contain Li₄Ti₅O₁₂. This invention also discloses anode film so prepared and thin film battery using such anode film.

These and other objectives and advantages of this invention may be clearly understood by those skilled in this art from the detailed description by referring to the following drawings.

### BRIEF DESCRIPTION OF THE DRAWINGS

FIG. 1 shows the X-ray powder diffraction pattern of the Li₄Ti₅O₁₂ target of this invention.

FIG. 2 shows the XRD diffraction patterns of Li₄Ti₅O₁₂ films deposited on Au/Ti/SiO₂/Si substrates at various sputtering temperatures.

FIGS. 3a-3d are SEM photographs showing the surface textures of Li₄Ti₅O₁₂ films deposited on Au/Ti/SiO₂/Si substrates at various sputtering temperatures.

FIGS. 4a-4d are SEM photographs showing cross-sectional views of Li₄Ti₅O₁₂ films deposited on Au/Ti/SiO2/Si substrates at various sputtering temperatures.

FIGS. 5a-5d show current density vs. voltage relations of Li₄Ti₅O₁₂ films deposited on Au/Ti/SiO2/Si substrates at various sputtering temperatures.

FIG. 6 shows the discharge curves of the invented Li₄Ti₅O₁₂ films prepared at various sputtering temperatures.

### DETAILED DESCRIPTION OF THE INVENTION

According to the present invention, when preparing the invented anode film for thin film battery, a target material that is able to supply Li and Ti ions and a substrate comprising a base layer, a buffer layer and a noble metal current collector layer are first prepared. A LiMO layer is sputtered onto the substrate in a vacuum chamber at high temperature. The anode film for thin film battery of this invention is thus obtained. In this invention, the noble metal current collector layer may contain noble metals such as silver, gold, platinum etc. and their alloy or oxides. The sputtering temperature may be above 300° C., preferably above 500° C. and most preferably above 650° C. The anode film so prepared contains Li₄Ti₅O₁₂.

Steps of the preparation of the anode film for thin film battery will be described in details in the followings.

Preparation of Li₄Ti₅O₁₂ Target

Sinter the desired target by the solid-state reaction method. A composition of Li₂CO₃ and TiO₂ (rutile phase) in a proper ratio is prepared as the initial material. The composition is mixed and ground. Calcine the mixed powders in a high temperature furnace at 800° C. for 15 hours. Grind the product again to obtain white powders in fine particle. Cold press the product under 12,600 Kg with a hydraulic presser. Sinter the pellet at 950° C. for 25 hours to obtain the desired target. A small amount of powder is scratched and collected for the structural analysis using an X-ray difractometer (MAC MXP3).

Preparation of Substrate

Prepare a SiO2/Si (100) layer as base layer for the substrate. Clean the base layer in organic solvents such as acetone, methanol and isopropanol respectively in sequence in an ultrasonic vibrator. Sputter a buffer layer and then a noble metal current collector layer using a DC magnetron sputtering.

The noble metal layer functions as the current collector to supply and collect electrons. Applicable material for the noble metal layer includes silver, gold, platinum, palladium etc. and their alloys or oxides. Other material or composition that is applicable as the current collector and helpful to the crystallization of the anode film may also be used in this invention. In the embodiments of this invention, gold is selected as major material of the noble metal current collector. The thickness of the noble metal layer may be 20 to 5,000 angstrom, preferably 500 to 2,000 angstrom. Generally speaking, a noble metal layer of 1,000 angstrom is applicable as the current collector layer.

The buffer layer is used to improve the adhesion between the noble metal layer and the base layer. Applicable material for the buffer layer includes Ti, Co, Cr, Mo, Zr, W etc., and their alloys or silicates. Thickness of the buffer layer may be 10-1,000 angstrom, preferably about 100 angstrom.

Preparation of Anode Film

Adhere the substrate so prepared onto a substrate holder using silver pastes. On a test sample for the electrochemical character analysis, one corner of the substrate is covered by a Si substrate, such that this area may be connected with an electrode wire. Dry the silver paste and position the substrate holder into a vacuum chamber. Deposit the target material onto the substrate under a vacuum condition.

Method for depositing the target material onto the substrate is not limited to any particular method or machine. In the embodiments of this invention, the radio frequency magnetron sputtering is applied. Before sputtering, the pressure of the vacuum chamber is kept to below 10⁻⁵ torr using a mechanical pump and a diffusing pump.

Heat the substrate holder at a rate of 5° C./min until desired working temperature. The working temperature is preferably within the range of high temperature, such as above 300° C., preferably above 500° C. Excellent effects are always obtained if the working temperature is above 700° C.

Inject the working gas of 30 sccm with a mass flow controller. The working gas may be a composition of Ar and O₂, with a ratio of about 3:2. The pressure of the chamber is controlled under about 30 mtorr.

Ignite the plasma and increase the sputtering power to a working value. Presputter the surface of the target for 20 minutes to remove contaminants and then open the shutter to start the deposition of the film. The deposition time may be depended on actual needs. Generally speaking, the deposition may be completed in about 2 hours. After completion, lower the temperature of the chamber at rate of 5° C./min.

Measurements and Observations

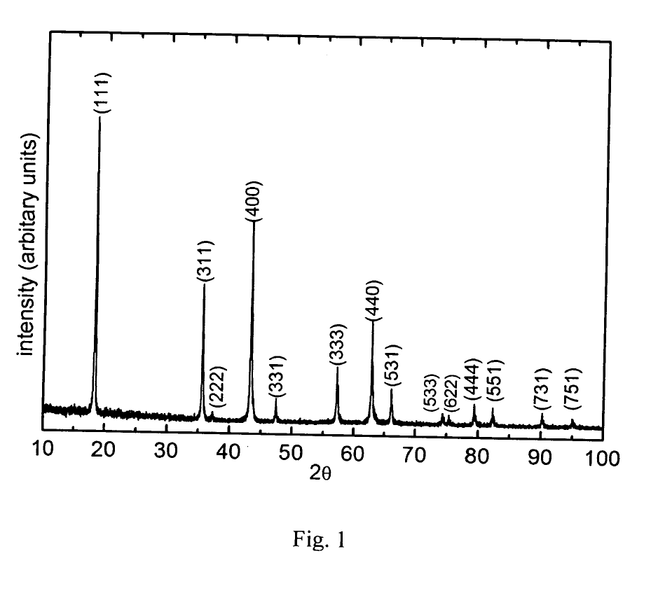

Measure the film structure and its crystallinity with an X-ray diffractometer (MAC MXP3). Use Cu—Kα (wave length λ−1.5405 angstrom) as the incident light source. Measure θ/2θ diffraction curve under the working voltage of 40 KV, working current of 30 mA, at a scanning speed of 2 degree/min. FIG. 1 shows the X-ray powder diffraction spectrum of the Li₄Ti₅O₁₂ target of this invention. From this figure it is shown that the Li₄Ti₅O₁₂ target sintered at high temperature has a pure phase of spinel structure.

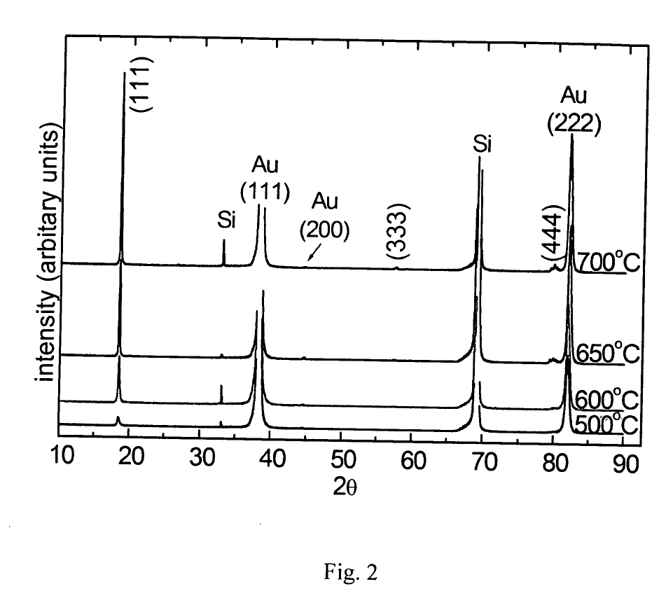

FIG. 2 shows the XRD diffraction patterns of Li₄Ti₅O₁₂ films deposited on Au/Ti/SiO2/Si substrates at various sputtering temperatures. As shown in these figures, when the temperature of substrate is 500° C. during the sputtering of the Li₄Ti₅O₁₂ film, the film so prepared possesses a crystallized spinel structure. As the sputtering temperature is increased, the crystallinity is prominently improved and its prefered orientatiion is the (111) direction.

Observe the surface texture, size of crystal particles, cross-sectional view and thickness of film using a field-emission scanning electron microscope. Cut a groove at the rear surface of the sample using a diamond knife and bend the sample to divide, and thus a cross section of the Li₄Ti₅O₁₂ film is obtained. Affix the sample on a conductive tape vertically and observe the cross section of the sample using a JEOL-6500 scanning electron microscope.

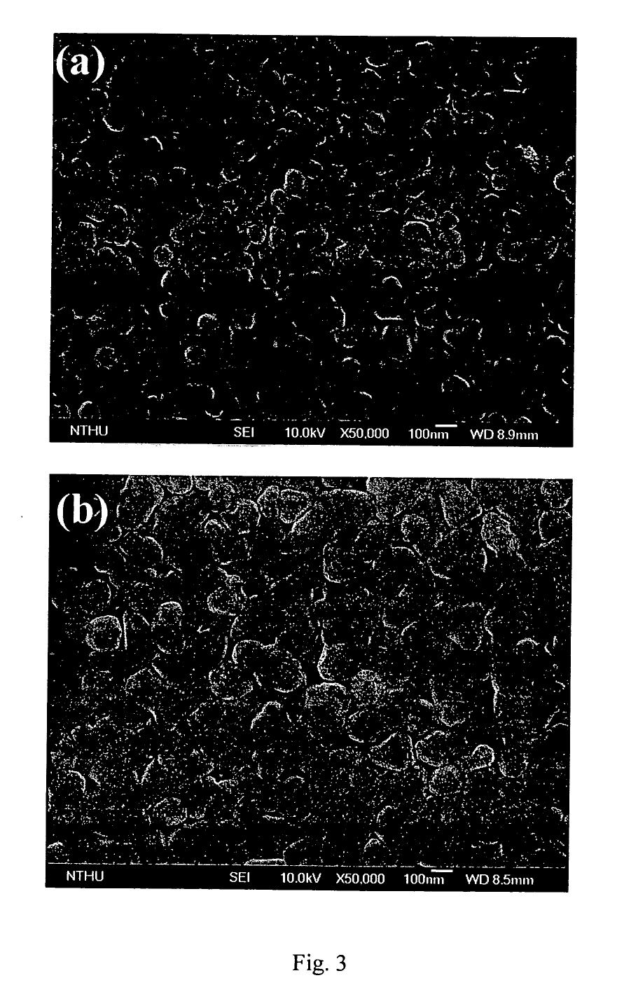

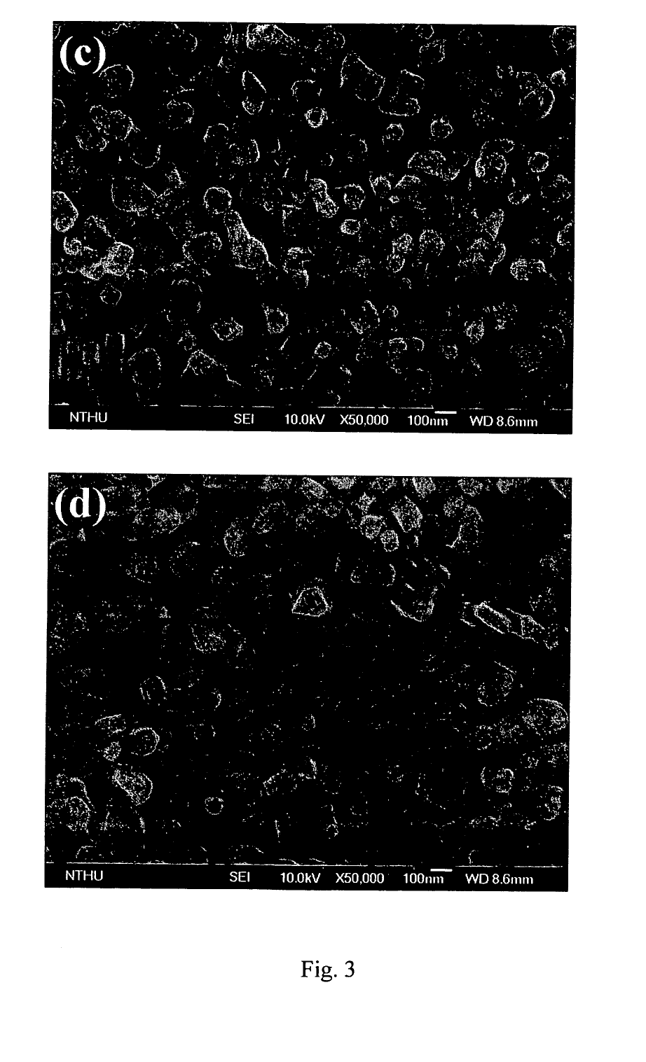

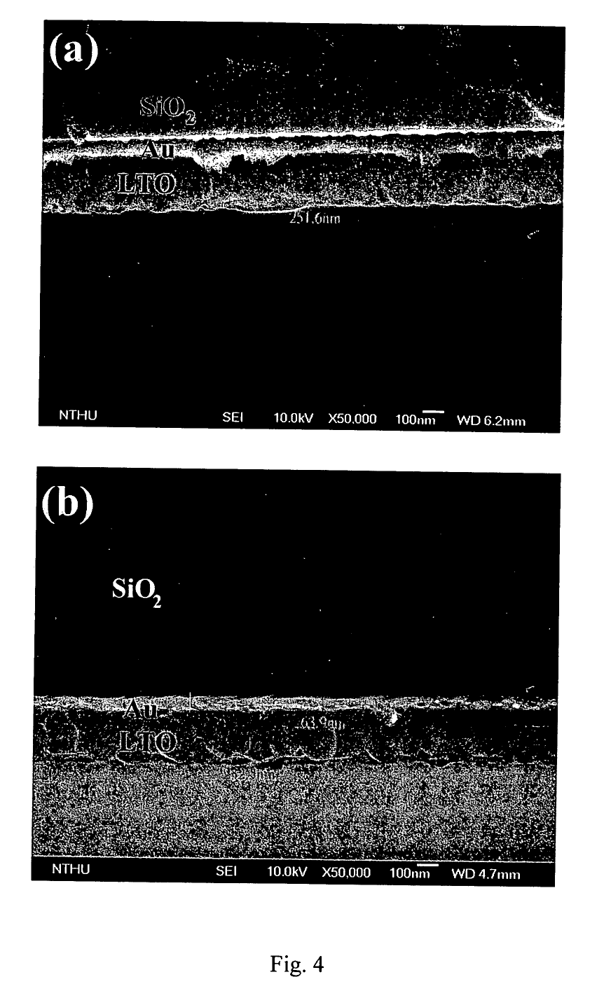

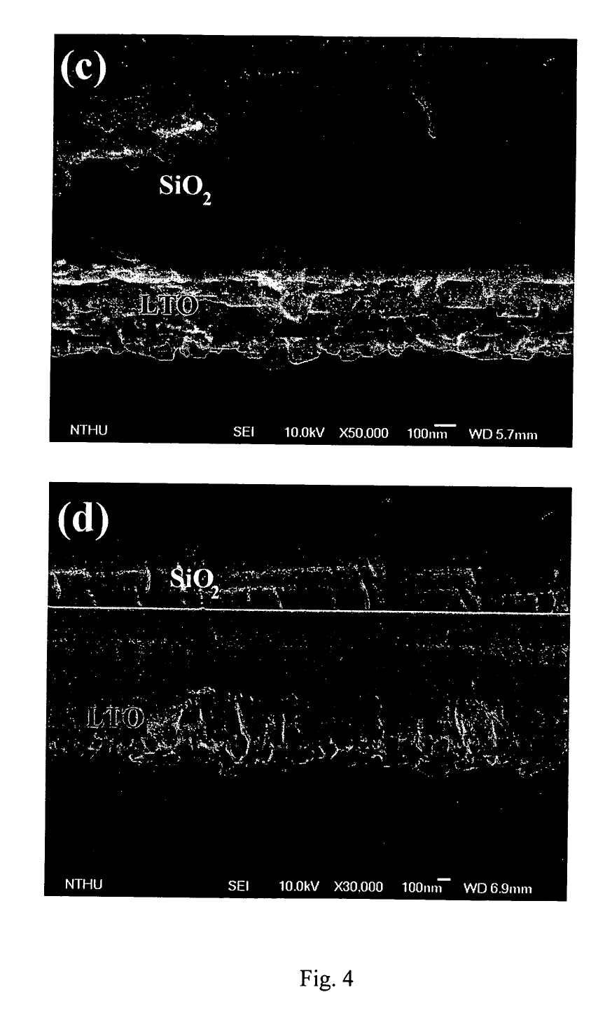

FIGS. 3a-3d are SEM photographs showing the surface textures of Li₄Ti₅O₁₂ films deposited on Au/Ti/SiO2/Si substrates at various sputtering temperatures. FIGS. 4a-4d are SEM photographs showing cross-sectional views of Li₄Ti₅O₁₂ films deposited on Au/Ti/SiO2/Si substrates at various sputtering temperatures. As shown in these figures, the film deposited at 500° C. has a closed packed columnar texture. While the sputtering temperature is increased, size of the grain increases prominently, and the closed-packed texture is still maintained. When the sputtering temperature is larger than 650° C., the surface of the film exhibits a columnar texture with high porosity.

Measurements of Electrochemical Features

Use the solution of 1 M LiPF6 dissolving in an EC/EMC (1:1) solution as the electrolyte. In a glove box (DLX-001-D MOD, Vacuum Atmospheres Company), the Li₄Ti₅O₁₂ film and the electrolyte are positioned in a mold. Use the Li₄Ti₅O₁₂ film as one electrode and a Li-metal foil as the other. The electrodes are divided using an isolation membrane to avoid the electrical short. Seal the upper cover with an O-ring. A test battery is obtained.

Use the cyclic voltammogram measurement to analyze the redox peaks of the Li₄Ti₅O₁₂ film and to check the electrochemical property of the film. The measurement range is between the voltages of 1 to 2 V at the scanning rate of 0.5 mV/s.

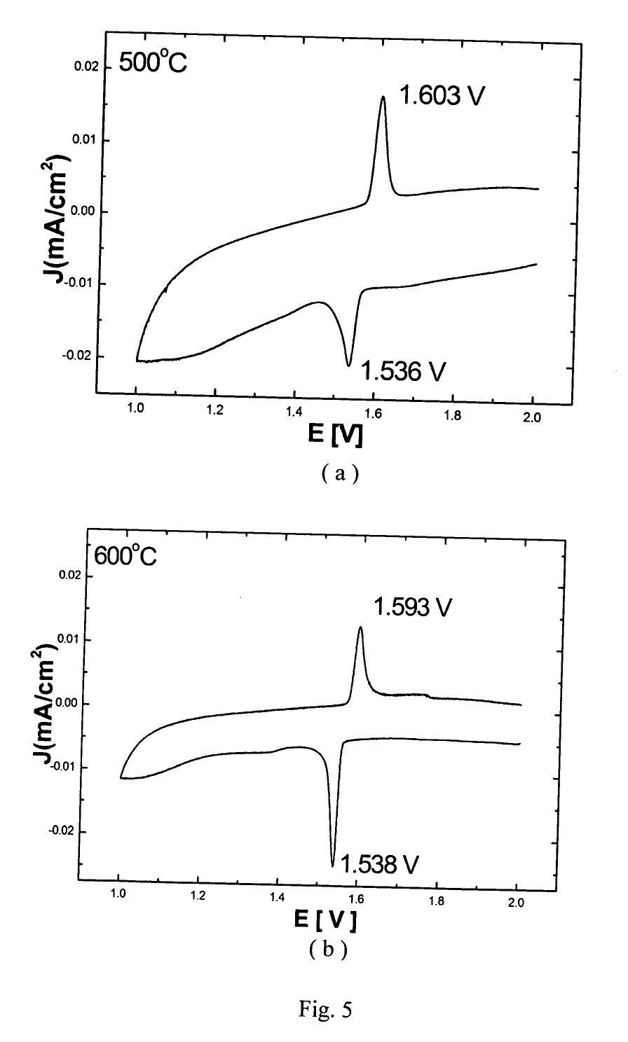

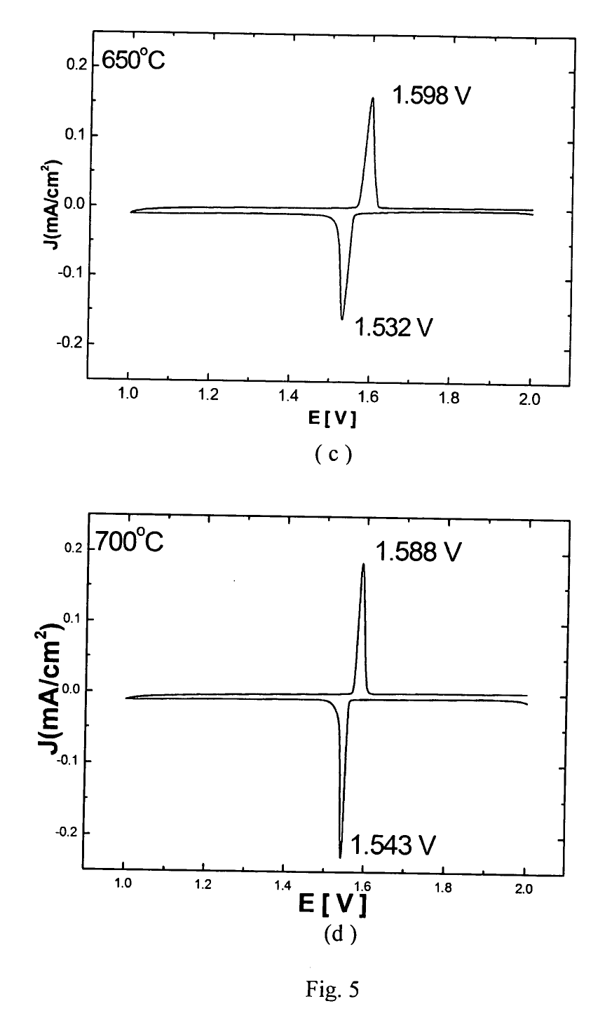

FIGS. 5a-5d show current density vs. voltage relations of Li₄Ti₅O₁₂ film deposited on Au/Ti/SiO2/Si substrates at various sputtering temperatures in test batteries. These figures show that, even though the samples are prepared at different sputtering temperatures, a pair of redox peaks due to the change between the spinel and rock-salt phase under the range of 1.5 V to 1.6 V is obtained and electrochemical reversibility of the insertion and extraction to and from the electrodes of the Li ions is observed. The redox peaks of samples prepared at different sputtering temperatures are different in shape and in scale of current density. As the sputtering temperature is increased, the film as deposited presents better crystallinity and greater current density, as increased at the power level, as shown in FIG. 5d. In addition, the votalges of oxidiation and reduction are closer while the sputtering temperature increases. This indicates that the extraction and insertion of Li ions are easier in the films grown in higher temperature.

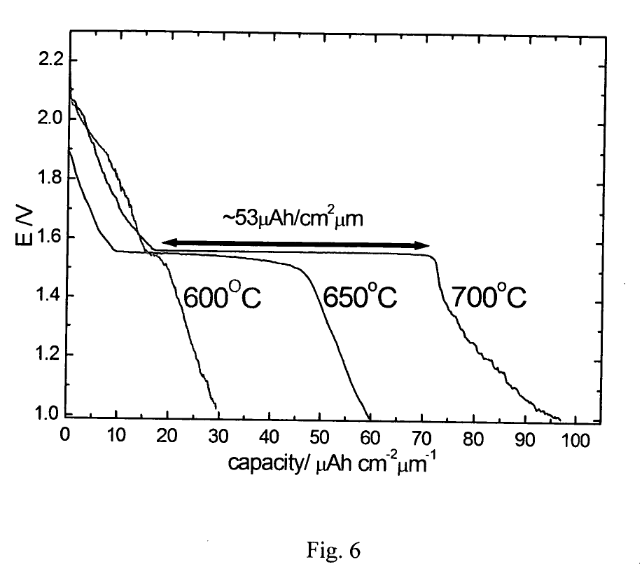

Charge and discharge the test battery at a constant current (10 μA/cm2) in a range of 1 V to 2 V. FIG. 6 shows the discharge curves of the invented Li₄Ti₅O₁₂ films prepared at various sputtering temperatures. As shown in this figure, the film depositing at 700° C. possesses a capacity about 53 μA/cm² μm, which this value is greater than that of film depositing at 600° C. This result is consistent with what was observed in the cyclic voltammogram measurement. In addition, when the sputtering temperature is increased, the discharge curve at about 1.55V becomes flatter. The film depositing at 700° C. presents a flat discharge curve that is almost horizontal.

It has been observed using the cyclic voltammogram method and the constant current charge-discharge measurement that when the sputtering temperature is above 650° C., the capacity of the battery using the invented film electrode will tremendously increase.

As the present invention has been shown and described with reference to preferred embodiments thereof, those skilled in the art will recognize that the above and other changes may be made therein without departing from the spirit and scope of this invention.

What is claimed is:

1. Method for preparing an anode film for thin film battery, comprising the steps of:
preparing a target material to supply Li and metal ions;
preparing a substrate comprising a base layer, a buffer layer and a noble metal current collector layer;
sputtering a LiMO layer on said substrate in vacuum chamber at the temperature above 300° C., wherein M represents a metal material; and
reducing said temperature to obtain said anode film.

2. The method according to claim 1, wherein said M metal comprises at least one selected from the group consisted of Ti, Co, Cr, Mo, Zr, W, their alloys and oxides.

3. The method according to claim 1, wherein said noble metal comprises at least one selected from the group consisted of silver, gold, platinum, palladium and their alloys or oxides.

4. The method according to claim 3, wherein said noble metal is gold.

5. The method according to claim 1, wherein said noble metal is sputtered onto said substrate at the temperature above 20° C.

6. The method according to claim 1, wherein said LiMO layer is sputtered onto said substrate at the temperature above 300° C.

7. The method according to claim 1, wherein said LiMO layer is Li₄Ti₅O₁₂ layer.

8. The method according to claim 1, wherein said buffer layer is metal layer.

9. The method according to claim 8, wherein said buffer layer is Ti layer.

10. The method according to claim 1, wherein thickness of said buffer layer is between 10-1,000 angstrom and thickness of said noble metal layer is between 20-5,000 angstrom.

11. A film electrode for thin film battery prepared according to any one of claims 1-10.

12. Method for preparing a thin film battery, comprising the steps of:
preparing an anode film;
preparing an electrolyte layer;
preparing a cathode film;
stacking said anode film, said electrolyte layer and said cathode layer in sequence, with each pair of adjacent layers being protected by shielding; and
encapsulating the assembly so obtained;
characterized in that said anode film electrode is prepared according to the following steps:
preparing a target material to supply Li and metal ions;
preparing a substrate comprising a base layer, a buffer layer and a noble metal current collector layer;
sputtering a LiMO layer on said substrate in vacuum chamber at the temperature above 300° C., wherein M represents a metal material; and
reducing said temperature to obtain said film electrode.

13. The method according to claim 12, wherein said M metal comprises at least one selected from the group consisted of Ti, Co, Cr, Mo, Zr, W, their alloys and oxides.

14. The method according to claim 12, wherein said noble metal comprises at least one selected from the group consisted of silver, gold, platinum, palladium and their alloys or oxides.

15. The method according to claim 14, wherein said noble metal is gold.

16. The method according to claim 12, wherein said noble metal is sputtered onto said substrate at the temperature above 20° C.

17. The method according to claim 12, wherein said LiMO layer is sputtered onto said substrate at the temperature above 300° C.

18. The method according to claim 12, wherein said LiMO layer is Li₄Ti₅O₁₂ layer.

19. The method according to claim 12, wherein said buffer layer is metal layer.

20. The method according to claim 19, wherein said buffer layer is Ti layer.

21. The method according to claim 12, wherein thickness of said buffer layer is between 10-1,000 angstrom and thickness of said noble metal layer is between 20-5,000 angstrom.

22. A thin film battery prepared according to any one of claims 12-21.
